(19) United States
(12) Patent Application Publication
(10) Pub. No.: US 2007/0252299 A1
(43) Pub. Date: Nov. 1, 2007

(54) Synchronization of precursor pulsing and wafer rotation

(75) Inventors: Maitreyee Mahajani, Saratoga, CA (US); Joseph Yudovsky, Campbell, CA (US); Yi-Chiau Huang, Fremont, CA (US); Kaushal Singh, Santa Clara, CA (US); Veronica McCarthy, San Jose, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/413,658

(22) Filed: Apr. 27, 2006

(51) Int. Cl. C23C 16/01

(52) U.S. Cl. 264/81

(57) ABSTRACT

A method for synchronizing the rotation of a substrate boat with material deposition is disclosed. Whenever support rods of the substrate boat rotate past a deposition source, they will block deposition gas from reaching certain portions of the substrate. By stopping the deposition gas whenever the support rods are located between the substrate and the deposition source, a uniform deposition can be achieved.

### BACKGROUND OF THE INVENTION

1. Field of the Invention

Embodiments of the present invention generally relate to deposition processes that are synchronized with wafer rotation.

2. Description of the Related Art

The effectiveness of a substrate fabrication process is often measured by two related and important factors, device yield and cost of ownership. These factors are important because they directly affect the cost to produce an electronic device and therefore a device manufacturer's competitiveness within the marketplace. The cost of ownership, while affected by a number of factors, is greatly affected by the number of substrates processed per hour. Batch processing has become a popular method to reduce the cost of ownership. A batch processing chamber typically holds substrates in a substrate boat. Substrate boats can hold numerous substrates, but the support rods cause non-uniform deposition because they block the line of sight path between a deposition source and the substrate.

There is a need in the art to reduce the cost of ownership in electronic device manufacturing while also providing a uniformly deposited film onto a substrate.

### SUMMARY OF THE INVENTION

The present invention generally provides a method of synchronizing the rotation of a substrate within a batch processing chamber in relation to the precursor gas flow into the chamber. By turning off the precursor gas flow into the chamber whenever a support rod of the substrate boat passes in front of the precursor gas injector panel, a uniform film can be deposited on a substrate.

In a first embodiment, a method for depositing a layer on a substrate is disclosed. The method involves rotating a substrate holder within a chamber, providing a deposition material to the substrate as the substrate holder rotates, and stopping the provision of a deposition material to the substrate when a vertically extending rod is located between the source and the substrate. The substrate holder has at least one vertically extending rod located at a perimeter of the substrate. The vertically extending rod extends to a height greater than the substrate.

In a second embodiment, an atomic layer deposition method is described. The method involves providing a substrate boat, rotating the substrate boat within a chamber, providing a first precursor from at least one injection port to the substrate while the substrate boat rotates, stopping the provision of the first precursor as each vertically extending rod rotates to a location between the injection port and the substrate, and providing the first precursor from the injector port to the substrate after the rod has rotated past the injection port. The substrate boat has a cap portion, a base portion, and a plurality of rods extending between the cap portion and the base portion. Each rod has at least one notch. An edge of a substrate can rest within one notch on each rod. The injection ports have an opening in a plane perpendicular to the substrate.

In a third embodiment, a method of depositing a layer on a substrate is described. The method involves providing a substrate boat within a chamber, rotating the substrate boat, and depositing material onto the substrate as the substrate boat rotates. The material is provided from a deposition source. The substrate boat has a cap portion, a base portion, and a plurality of rods extending between the cap portion and the base portion. Each rod has at least one notch. An edge of the substrate can rest within one notch on each rod. The depositing is synchronized with the rotation such that during the time that the rod is located between the deposition source and the substrate, deposition material is not provided from the deposition source.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic drawing of a wafer boat.

FIG. 2 is a schematic drawing of a support road with a notch.

FIG. 3 is a schematic drawing of a substrate resting within the notches of two support rods.

FIG. 4 is a schematic drawing of a wafer boat in relation to a deposition source.

FIG. 5 is a schematic drawing of a wafer boat in relation to a deposition source at another moment in time.

### DETAILED DESCRIPTION

The present invention describes a method of uniformly depositing films within a batch processing chamber. A particularly good batch processing chamber that can be used to practice the invention is described in U.S. patent application Ser. No. 11/249,555, filed Oct. 13, 2005, which is hereby incorporated by reference in its entirety. The invention is illustratively described below with reference to a FLEXSTAR™ system, available from Applied Materials, Inc., Santa Clara, Calif.

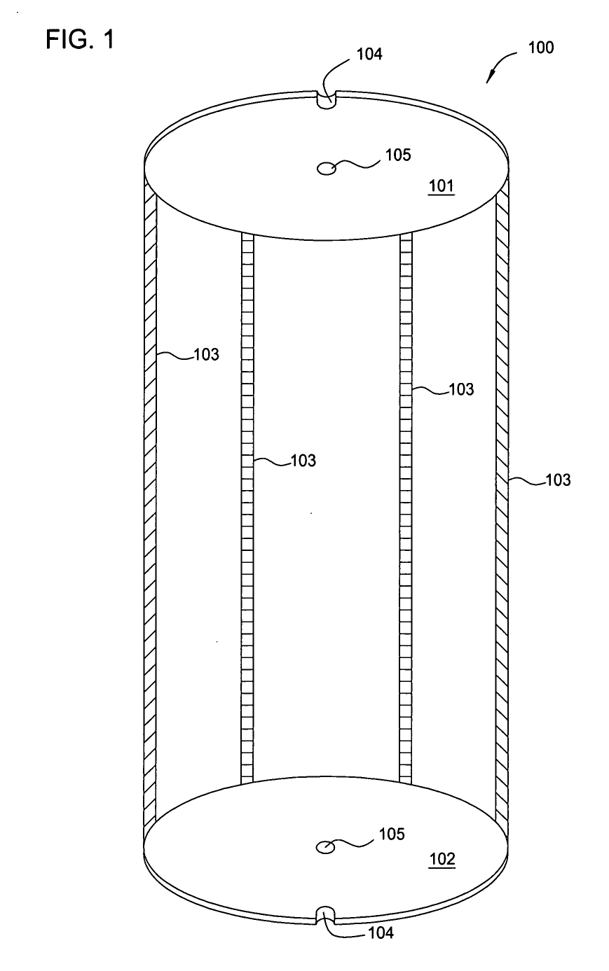

FIG. 1 is a schematic drawing of a substrate boat used in batch processing chambers. Other examples of substrate boats that can be used in batch processing are described in U.S. patent application Ser. No. 11/216,969, filed Aug. 31, 2005, which is hereby incorporated by reference in its entirety. FIG. 1 shows a substrate boat 100 that can be used in the present invention. The substrate boat 100 has a cap portion 101 and a base portion 102. The cap portion 101 and the base portion 102 are connected by several support rods 103. The cap portion 101 and the base portion 102 each have a slot 104 and a hole 105. The slots 104 are locations where the substrate boat 100 can be grasped for removal from the chamber, insertion into the chamber, and manipulation outside of the chamber. The holes 105 are for connection to a rotation mechanism that will rotate the substrate boat 100 during processing.

The substrate boat 100 shown in FIG. 1 has four vertically extending support rods 103. It should be understood that more or less support rods 103 can be present so long as sufficient support is provided for a substrate during processing. The support rods 103 can be evenly spaced or they can be unevenly spaced around the circumference of the substrate boat 100.

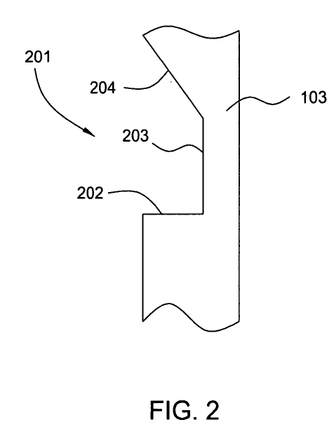

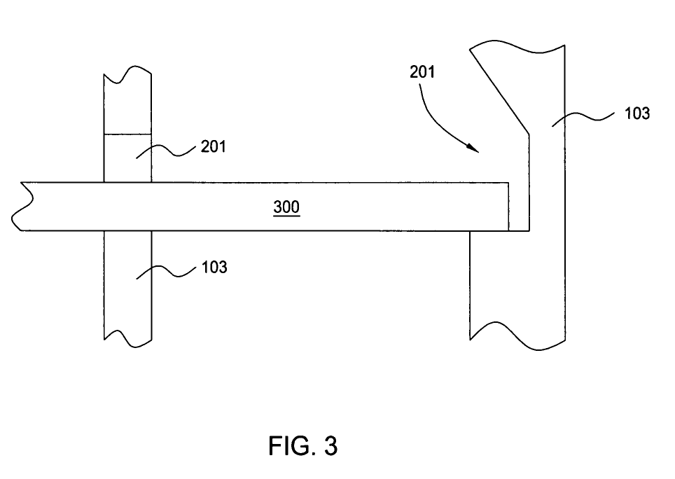

Each support rod 103 has a plurality of notches 201. FIG. 2 shows a close up view of a notch 201 on a support rod 103. The notch 201 has a flat bottom surface 202 on which the substrate will rest, a vertical side surface 203, and a slanted surface 204. It should be understood that the notch 201 need not be an opening within the support rod 103. Instead of a notch 201, a ledge extending from the support rod 104 could be used. Additionally, the shape of the notch 201 is not limited. So long as a notch or equivalent thereof can hold a substrate within the substrate boat without interfering with the deposition, it will be sufficient. FIG. 3 shows a substrate 300 supported by two support rods 103, each having a notch 201.

The substrate boat 100 can be designed to hold any number of substrates. The substrate boat 100 can be designed to hold 1 to 100 substrates 300, with 51 substrates being preferred.

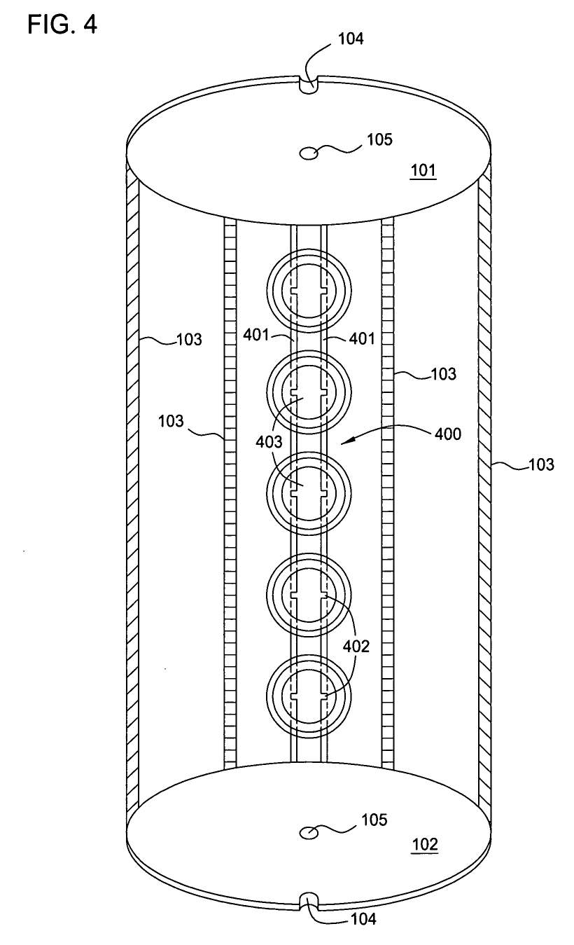

To deposit a layer by atomic layer deposition (ALD) using the batch processing chamber, two separate precursors will be provided to the substrate 300. A particularly good ALD process that can be practiced using the present invention is described in U.S. patent application Ser. No. 11/232,455, filed Sep. 21, 2005, which is hereby incorporated by reference in its entirety. The precursors will be provided to the substrate 300 from a deposition source located to the side of the substrate 300. The deposition source is an injector assembly 400 that will provide the precursor gases through gas tubes 401 to outlet holes 402 within injection ports 403. FIG. 4 shows the injector assembly 400 together with a substrate boat 100. The precursor gas is then dispersed within the chamber and, ideally, evenly over the substrates 300. So long as nothing lies between the injection ports 403 and the substrates 300, the precursor will be uniformly dispersed to the substrate 300.

While the injector assembly 400 has been shown with only five injection ports 403, it should be understood that any number of injection ports 403 can be present. Ideally, the number of injection ports 403 will be equal to the maximum number of substrates 300 that can be held by the substrate boat 100 at one time. Additionally, it should be understood that the size of the injection ports 403 shown in the figures is not a representative size in relation to the substrate boat 100. The injection ports 403, gas tubes 401, and holes 402 have been enlarged for ease of viewing.

As the substrate boat 100 rotates, the support rods 103 will inevitably block the line of sight path between the injection ports 403 and the substrates 300. When the support rods 103 are between the substrates 300 and the injection ports 403, the precursor will not be evenly distributed to the substrate 300. The area of the substrate 300 that is blocked by the support rods 103 will not receive an equal amount of precursor gas as the rest of the substrate 300. Therefore, the precursor gas will not be uniformly provided to the substrate 300. When the precursor is not evenly provided to the substrate 300, an uneven film will be deposited.

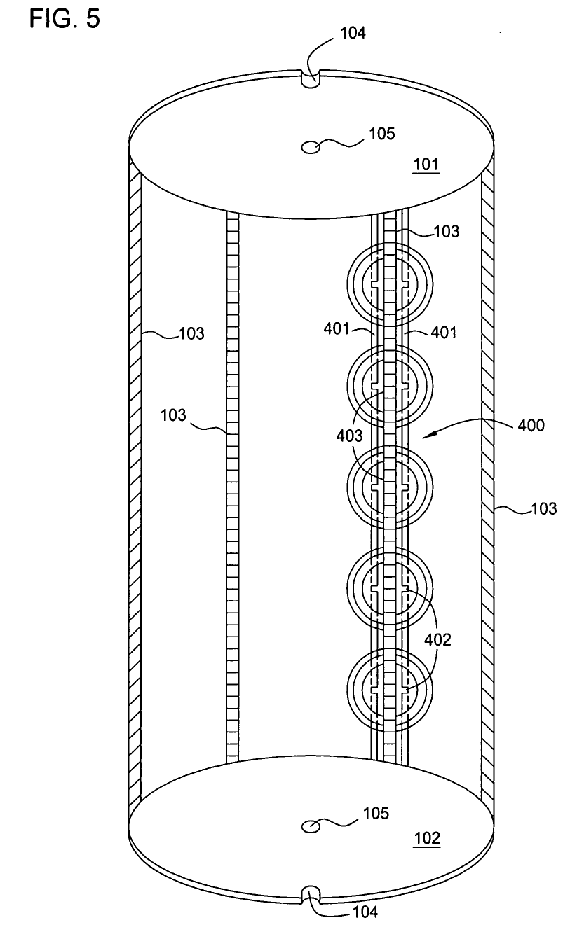

FIG. 5 shows the injector assembly 400 when it is behind one of the support rods 103 of the substrate boat 100. When the support rod 103 is between the substrate 300 and the injector assembly 400, portions of the substrate 300 that are behind the support rod 103 will not receive any of the precursor material. At the same time, the areas of the substrate 300 that are not blocked by the support rod 103 will be exposed to precursor material. Therefore, the precursor will not be evenly distributed to the substrate 300.

To prevent uneven distribution, the precursor is delivered to the substrate in synchronized pulses in the following manner. As soon as the support rods 103 begin to get in between the substrate 300 and the injector assembly 400, the precursor gas flow is shut off and the wafer boat 100 continues to rotate. Once the support rod 103 is clear of the injector assembly 400, the precursor gas flow is restarted.

Synchronizing the precursor gas flow pulses with the rotation of the substrate boat 100 allows the precursor gas to always be uniformly provided to all areas of the substrate 300. The synchronization of the precursor gas flow pulses in relation to the support rods 103 can be set for rods that are evenly spaced around the substrate boat 100. If the support rods are not evenly spaced around the substrate boat 100, then the synchronization must take into account the location of the support rods 103 so that the precursor gas is timed to shut off whenever the support rods 103 block the line of sight path between the substrate 300 and the injector assembly 400.

The synchronization can be performed in numerous manners. One manner of synchronization involves a specified timing schedule. The specified timing schedule involves controlling the precursor to be provided to the substrate 300 at certain time intervals. The time intervals are predetermined based upon a preset rotation rate of the substrate boat 100. The substrate boat 100 can be rotated at about 1 to about 30 rpm. Once the rotation rate is chosen and the support rod 103 spacing is known, the timing sequence of the precursor gas can be easily calculated.

Another manner of synchronizing the precursor gas with the rotation of the substrate 300 is to have a sensing mechanism that senses when the support rod 103 is beginning to block the line of sight path between the injector assembly 400 and the substrate. An additional sensor would be provided to sense when the support rod 103 is no longer blocking the line of sight path between the substrate 300 and the injector assembly 400. The sensors would provide feedback to a central control unit that would control when and for how long the precursor gas is provided. Additional synchronization manners not mentioned herein could also be used without departing from the spirit of the invention.

For a two component composite, the ALD process will typically be broken down into two separate cycles. In the first cycle, the first precursor will be provided to the substrate 300. In one embodiment, the first precursor will be supplied to the substrate 300 for about 2 seconds to about 2 minutes. In another embodiment, the first precursor will be supplied to the substrate 300 for about 15 seconds or less. After the first precursor is provided to the substrate 300, the chamber is evacuated to remove the first precursor gas. Following the evacuation, an inert purge gas is supplied to the chamber. Following the purge gas supply, the chamber will be evacuated. In one embodiment, the evacuation-purge-evacuation lasts about 2 seconds to about 5 minutes. In another embodiment, the evacuation-purge-evacuation lasts about 20 seconds. Following the purge, the second precursor is provided to the substrate 300. In one embodiment, the second precursor will be supplied to the substrate 300 for about 2 seconds to about 2 minutes. In another embodiment, the second precursor is provided to the substrate 300 for about 15 seconds or less.

While a two component composite has been described above, it is to be understood that additional cycles can be present. The number of cycles will depend upon the number of precursors to be supplied. For example, in a three component system, a third precursor cycle will be necessary. All additional precursor cycles can be performed for the same time periods discussed above in relation to the first and second precursors. Additionally, the order that the precursors will be supplied depends upon the desired film to be formed. Between each precursor cycle, the evacuation-purge-evacuation described above will be performed. During the time period that the precursor gases are provided to the substrate 300, it is to be understood that the synchronization of the substrate 300 rotation and the precursor gas flow as described above are occurring.

By synchronizing the rotation of the substrate boat with the timing of the deposition, films can be uniformly deposited on multiple substrates simultaneously. The synchronization of the substrate boat rotation and the timing of the deposition allow uninterrupted gas flow distribution to the substrate which results in improved film uniformity. Otherwise, uniformity degrades around the rod location.

It is to be understood that any conventional deposition method such as physical vapor deposition, atomic layer deposition, and chemical vapor deposition may be performed by the current invention. Additionally, any conventional substrate can be processed by the present invention including semiconductor substrates.

While the foregoing is directed to embodiments of the present invention, other and further embodiments of the invention may be devised without departing from the basic scope thereof, and the scope thereof is determined by the claims that follow.

We claim:

1. A method for depositing a layer on a substrate comprising:
rotating a substrate holder within a chamber, said substrate holder comprising at least one vertically extending rod located near an outer perimeter of said substrate, said vertically extending rod extending to a height greater than the substrate;
providing a deposition material to said substrate as said substrate rotates; and
stopping said providing of a deposition material to said substrate when said at least one vertically extending rod is located between said source and said substrate.

2. The method as claimed in claim 1, wherein the method for depositing is atomic layer deposition.

3. The method as claimed in claim 1, further comprising,
exhausting said chamber;
providing a second deposition material to said substrate as said substrate rotates; and
stopping said providing of a second deposition material to said substrate when said at least one vertically extending rod is located between said source and said substrate.

4. The method as claimed in claim 1, wherein said at least one vertically extending rod comprises a plurality of rods.

5. The method as claimed in claim 4, wherein said rods are evenly spaced around the perimeter of said substrate.

6. The method as claimed in claim 4, wherein said rods are not evenly spaced around the perimeter of said substrate.

7. The method as claimed in claim 1, further comprising providing said first deposition material after said at least one vertically extending rod has rotated past said source.

8. An atomic layer deposition method comprising:
providing a substrate boat, said substrate boat comprising:
a cap portion;
a base portion;
a plurality of rods extending between said cap portion and said base portion, each rod comprising at least one notch, wherein an edge of a substrate can rest within one notch on each rod;
rotating said substrate boat within a chamber;
providing a first precursor from at least one injection port to said substrate while said substrate boat rotates;
stopping said providing of the first precursor as the vertically extending rod rotates to a location between said injection port and said substrate;
providing said first precursor from said injector port to said substrate after each said rod has rotated past said injection port.

9. The method as claimed in claim 8, further comprising,
exhausting said chamber;
providing a second precursor from at least one injection port to said substrate while said substrate boat rotates; and
stopping said providing of the second precursor as each vertically extending rod rotates to a location between said injection port and said substrate.

10. The method as claimed in claim 8, wherein said notches on each rod are aligned with notches on all other rods such that said substrate is substantially level when placed within said substrate boat.

11. The method as claimed in claim 8, wherein said rods are evenly spaced around the perimeter of said substrate.

12. The method as claimed in claim 8, wherein said rods are not evenly spaced around the perimeter of said substrate.

13. The method as claimed in claim 8, wherein said at least one injection port comprises a plurality of injection ports.

14. A method of depositing a layer on a substrate comprising:
providing a substrate boat within a chamber, said substrate boat comprising:
a cap portion;
a base portion;
a plurality of rods extending between said cap portion and said base portion, each rod comprising at least one notch, wherein an edge of a substrate can rest within one notch on each rod;
rotating said substrate boat;
depositing material onto said substrate as said substrate boat rotates, said material provided from a deposition source, wherein said depositing is synchronized with said rotation such that during the time that said rod is located between said deposition source and said substrate, deposition material is not provided from said deposition source.

15. The method as claimed in claim 14, wherein said method of depositing comprises chemical vapor deposition, physical vapor deposition, or atomic layer deposition.

16. The method as claimed in claim 14, further comprising,
exhausting said chamber;
depositing a second material onto said substrate as said substrate boat rotates, said second material provided from a second deposition source, wherein said depositing is synchronized with said rotation such that during the time that each said rod is located between said second deposition source and said substrate, deposition material is not provided from said second deposition source.

17. The method as claimed in claim 14, wherein said notches on each rod are aligned with notches on all other rods such that said substrate is substantially level when placed within said substrate boat.

18. The method as claimed in claim 14, wherein said rods are evenly spaced around the perimeter of said substrate.

19. The method as claimed in claim 14, wherein said rods are not evenly spaced around the perimeter of said substrate.

20. The method as claimed in claim 14, wherein said deposition source comprises a plurality of injection ports.
